(19) United States
(12) Patent Application Publication
(10) Pub. No.: US 2006/0202235 A1
(43) Pub. Date: Sep. 14, 2006

(54) Solid-state imaging apparatus in which a plurality of pixels each including a photoelectric converter and a signal scanning circuit are arranged two-dimensionally

(76) Inventor: Hisanori Ihara, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/370,040

(22) Filed: Mar. 8, 2006

(30) Foreign Application Priority Data
Mar. 9, 2005 (JP) 2005-065810

(51) Int. Cl. H01L 27/148

(52) U.S. Cl. 257/223

(57) ABSTRACT

A solid-state imaging apparatus includes a semiconductor substrate, a photoelectric converter which is formed in a surface region of the semiconductor substrate and converts light into signal charges, and reading electrodes which read out the signal charges and supply the signal charges to a signal sensor. At least some of the reading electrodes are arranged adjacent to the circumference of an image-forming region with a fixed distance between the circumference and the center of the photoelectric converter.

### CROSS-REFERENCE TO RELATED APPLICATIONS

This application is based upon and claims the benefit of priority from prior Japanese Patent Application No. 2005-065810, filed Mar. 9, 2005, the entire contents of which are incorporated herein by reference.

### BACKGROUND OF THE INVENTION

1. Field of the Invention

The present invention relates to a solid-state imaging apparatus. More specifically, the invention relates to a complementary metal oxide semiconductor (CMOS) sensor in which a plurality of cells (pixels) each including a photoelectric converter and a signal scanning sensor are arranged two-dimensionally.

2. Description of the Related Art

Conventionally, a CMOS sensor has been proposed as a solid-state imaging apparatus that is characterized in that it uses a single power supply and it is driven by a low voltage. Such an apparatus is disclosed in, for example, Hyuck In Kwon et al., “The Analysis of Dark Signals in the CMOS APS Imagers From the Characterization of Test Structures”, IEEE Trans. Electron Devices, Vol. 51, pp. 178-184, February 2004. In the CMOS sensor, usually, a plurality of pixels each including a photoelectric converter and a signal scanning circuit are two-dimensionally arranged in column direction. The CMOS sensor so configured has recently decreased in size and increased in packaging density by miniaturization of pixels in accordance with the development of CMOS-sensor-equipped electronic devices.

However, the pixels of the CMOS sensor each include four transistors that compose the signal scanning circuit, such as a reading transistor, an amplifying transistor, a selecting transistor (address transistor) and a resetting transistor. As the pixels are simply miniaturized, the photoelectric converter (photodiode) reduces in area. This causes a problem in which saturation signals of pixel characteristics decrease and optical shot noise increases.

Like a charge-coupled device, the CMOS sensor is difficult to drive at high voltage and using a multiple power supply. Therefore, the CMOS sensor has the drawback that charges are likely to be left in the photodiode without being read out and such charges cause an afterimage to be formed. To prevent this, the following configuration is proposed. The gate electrode of a reading insulation gate transistor is provided to have the lowest potential in the vicinity of the center of the photoelectric converter (photoelectric converting region). This configuration is disclosed in, for example, Jpn. Pat. Appln. KOKAI Publication No. 11-274462.

In the proposed configuration, however, when the photoelectric converter decreases in area due to miniaturization of pixels, the gate electrode becomes difficult to form close to the center of the potential. The configuration is unsuitable for miniaturizing the pixels.

### BRIEF SUMMARY OF THE INVENTION

According to a first aspect of the present invention, there is provided a solid-state imaging apparatus comprising a semiconductor substrate, a photoelectric converter which is formed in a surface region of the semiconductor substrate and converts light into signal charges, and reading electrodes which read out the signal charges and supply the signal charges to a signal sensor, at least some of the reading electrodes being arranged adjacent to a circumference of an image-forming region with a fixed distance between the circumference and a center of the photoelectric converter.

### BRIEF DESCRIPTION OF THE SEVERAL VIEWS OF THE DRAWING

FIG. 1 is a plan view showing a configuration of a pixel of a CMOS sensor according to a first embodiment of the present invention;

FIG. 2A is a diagram of results of simulations of plane potentials formed by a reading gate electrode in the CMOS sensor according to the first embodiment of the present invention;

FIG. 2B is a diagram of results of simulations of plane potentials formed by a reading gate electrode in a prior art CMOS sensor;

FIG. 3 is a plan view showing a configuration of a pixel of a CMOS sensor according to a second embodiment of the present invention;

FIG. 4 is a plan view showing a configuration of a pixel of a CMOS sensor according to a third embodiment of the present invention;

FIG. 5 is a plan view showing a configuration of a pixel of a CMOS sensor according to a fourth embodiment of the present invention;

FIG. 6 is a plan view showing a configuration of a pixel of a CMOS sensor according to a fifth embodiment of the present invention;

FIG. 7 is a plan view showing a configuration of a pixel of a CMOS sensor according to a sixth embodiment of the present invention;

FIG. 8 is a plan view showing a configuration of a pixel of a CMOS sensor according to a seventh embodiment of the present invention;

FIG. 9 is a plan view showing a configuration of a pixel of a CMOS sensor according to an eighth embodiment of the present invention;

FIG. 10 is a plan view showing a configuration of a pixel of a CMOS sensor according to a ninth embodiment of the present invention;

FIG. 11 is a plan view showing another configuration of the pixel of the CMOS sensor shown in FIG. 10;

FIG. 12 is a plan view showing a configuration of a pixel of a CMOS sensor according to a tenth embodiment of the present invention; and

FIG. 13 is a plan view showing a configuration of a pixel of a CMOS sensor according to an eleventh embodiment of the present invention.

### DETAILED DESCRIPTION OF THE INVENTION

Embodiments of the present invention will be described with reference to the accompanying drawings. It should be noted that the drawings are schematic ones and the dimension ratios shown therein are different from the actual ones. The dimensions vary from drawing to drawing and so do the ratios of dimensions.

### First Embodiment

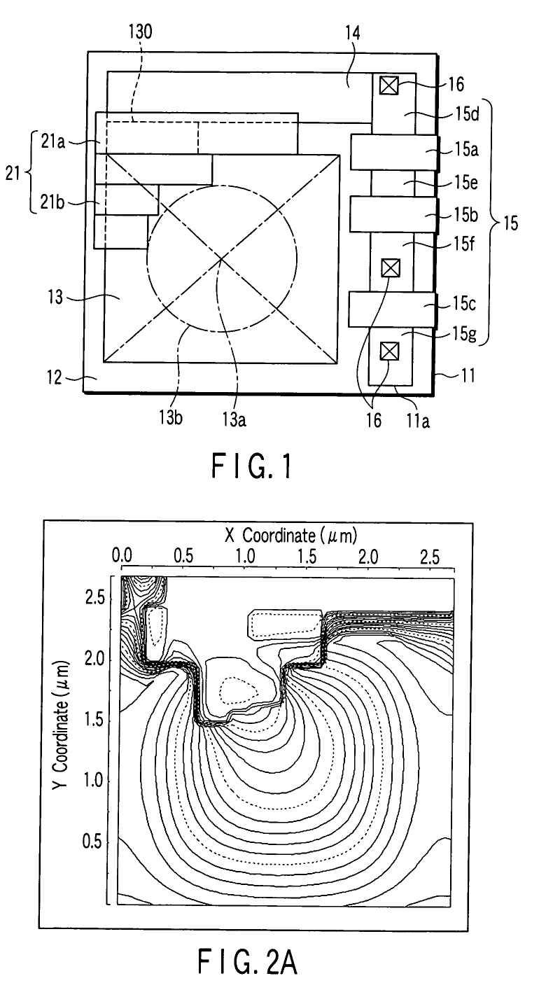

FIG. 1 shows a basic configuration of a CMOS sensor (solid-state imaging apparatus) according to a first embodiment of the present invention. Specifically, FIG. 1 shows one pixel (unit cell) of a pixel region of the CMOS sensor as an example of the configuration. Wiring is not shown for the sake of convenience.

As shown in FIG. 1, an element isolation region 12 having a shallow trench isolation (STI) structure is formed selectively in a surface region of a P-type semiconductor substrate (referred to as P-type substrate hereinafter) 11. A buried photodiode 13 serving as a photoelectric converter, a signal sensor 14 and a signal scanning circuit 15 are formed in an activation region of the P-type substrate 11 delimited by the element isolation region 12, or in a surface region of the P-type substrate 11 excluding the element isolation region 12. The buried photodiode 13 is quadrilateral (almost square), and a surface shield layer (not shown) is formed on the surface of the photodiode 13.

Of four transistors that compose the signal scanning circuit 15, for example, three insulated gate transistors are arranged in a P-type well region 11a in the surface region (activation region) of the P-type substrate 11. More specifically, a gate electrode 15a of an amplifying transistor, a gate electrode 15b of a selecting transistor (address transistor), and a gate electrode 15c of a resetting transistor are each selectively provided on the P-type well region 11a with an insulation film (not shown) interposed therebetween. N-type diffusion layers 15d, 15e, 15f and 15g serving as source and drain regions of the transistors are formed in the surface region of the P-type well region 11a excluding the gate electrodes 15a, 15b and 15c. A source/drain contact 16 is connected to each of the N-type source diffusion layers 15d, 15f and 15g. The P-type well region 11a is separated from the buried photodiode 13 by a given distance.

The signal sensor 14 is formed in the surface region (activation region) of the P-type substrate 11. The signal sensor 14 is formed of, e.g., an N-type diffusion layer. A portion of the signal sensor 14 is connected to the N-type diffusion layer (one of source and drain regions of the amplifying transistor) 15d. Another portion of the signal sensor 14 is connected to the buried photodiode 13 via a leading region 130.

The remaining one of the four transistors of the signal scanning circuit 15 is provided to correspond to the buried photodiode 13 and the signal sensor 14. This remaining transistor has a reading gate electrode (reading electrode) 21 that is made of, e.g., polysilicon. The gate electrode 21 includes part of the buried photodiode 13 and is provided on the surface of the P-type substrate 11 and almost between the signal sensor 14 and the buried photodiode 13. Part of the photodiode 13 is adjacent to the signal sensor 14. The gate electrode 21 is photoelectrically converted by the buried photodiode 13, so that the signal charges stored therein are supplied to the signal sensor 14.

The reading gate electrode 21 includes a first electrode section 21a and a second electrode section 21b connected to the first electrode section 21a. The first electrode section 21a is formed on the element isolation region 12 and between the signal sensor 14 and the buried photodiode 13, including part (leading region 130) of the buried photodiode 13. The first electrode section 21a is rectangular and extends along the signal sensor 14. On the other hand, the second electrode section 21b is formed by several electrode patterns. The distance between each of the electrode patterns and the center 13a of the buried photodiode 13 is almost fixed. In other words, the second electrode section 21b is provided on the buried photodiode 13 such that its electrode patterns are adjacent to the circumference of an image-forming region 13b with a fixed distance between the circumference and the center 13a of the buried photodiode 13. In the first embodiment, the second electrode section 21b is provided to correspond to almost one-fourth of the circumference of the image-forming region 13b. The electrode patterns of the second electrode section 21b are rectangular and different in size, and they are arranged in a stepwise manner along the circumference of the image-forming region 13b.

In the CMOS sensor so configured, a plurality of pixels are arranged two-dimensionally in row and column directions to form a pixel region.

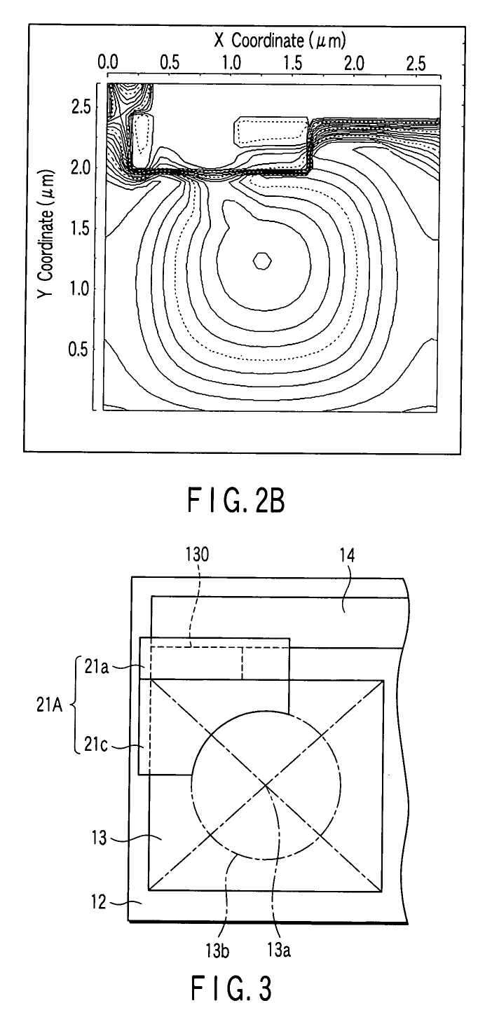

FIG. 2A shows results of simulations of plane potentials formed by the reading gate electrode 21 shown in FIG. 1. FIG. 2B shows results of simulations of plane potentials formed by a prior art reading gate electrode (corresponding to the first electrode section 21a only).

As is apparent from FIG. 2B, conventionally, an electric field does not extend so much from the reading gate electrode or an adequate voltage cannot be applied to a buried photodiode. The buried photodiode has the lowest part of a single potential corresponding to each of signal charges almost in the center of the photodiode. The prior art reading gate electrode has difficulty in reading signal charges from the buried photodiode; therefore, it is unsuitable for miniaturization of pixels.

In the first embodiment of the present invention, the second electrode section 21b is so provided that the distance between each of the electrode patterns and the center 13a of the buried photodiode 13 is almost fixed. A more adequate voltage can thus be applied to the buried photodiode 13 as shown in FIG. 2A. The buried photodiode 13 has the lowest part of a single potential corresponding to each of signal charges under the reading gate electrodes 21. The signal charges stored in the photodiode 13 can thus be supplied to the signal sensor 14 the most easily. As compared with the prior art reading gate electrode, the potential becomes lower, and read speed and responsivity become higher. Even when pixels are miniaturized, a larger amount of saturation current can be stored in the buried photodiode 13. The reading gate electrode 21 is therefore suitable for miniaturization of pixels.

The second electrode section 21b is provided adjacent to the circumference of the image-forming region 13b of the buried photodiode 13. In other words, the second electrode section 21b is provided only outside the image-forming region 13b so as to fall outside the focal area of an image-forming lens (not shown). There is no fear that the reading gate electrode 21 will hinder light from entering the buried photodiode 13 to lower the sensitivity of the CMOS sensor.

With the first embodiment, the signal charges can be read out of the buried photodiode the most as described above. Even when pixels are miniaturized, saturation signals can be prevented from reducing. Good saturation signals can be acquired even from fine pixels and, consequently, for example, optical shot noise can be suppressed. In the CMOS sensor, image characteristics can be prevented from deteriorating due to the miniaturization of pixels.

In the above first embodiment, the reading gate electrode 21 is formed by the first and second electrode sections 21a and 21b. However, the reading gate electrode 21 can be formed as a single component.

### Second Embodiment

FIG. 3 shows a basic configuration of a CMOS sensor (solid-state imaging apparatus) according to a second embodiment of the present invention. Specifically, FIG. 3 shows one pixel (unit cell) of a pixel region of the CMOS sensor as an example of the configuration. The second embodiment is directed to another configuration (shape) of the second electrode section of the reading gate electrode according to the first embodiment. The same components as those of FIG. 1 are denoted by the same reference numerals and their detailed descriptions are omitted.

In the second embodiment, a first electrode section 21a and a second electrode section 21c compose a reading gate electrode (polysilicon) 21A, as shown in FIG. 3. More specifically, the first electrode section 21a is formed on an element isolation region 12 and between a signal sensor 14 and a buried photodiode 13, including part (leading region 130) of the buried photodiode 13. The first electrode section 21a is rectangular and extends along the signal sensor 14. On the other hand, the second electrode section 21c is formed by at least one electrode pattern. The distance between the electrode pattern and the center 13a of the buried photodiode 13 is almost fixed. In other words, the second electrode section 21c is provided on the buried photodiode 13 such that it is adjacent to the circumference of an image-forming region 13b with a fixed distance between the circumference and the center 13a of the buried photodiode 13. In the second embodiment, the second electrode section 21c is provided to correspond to almost one-fourth of the circumference of the image-forming region 13b. The electrode pattern of the second electrode section 21c is curved such that a portion of the pattern which is adjacent to the circumference of the image-forming region 13b is curved.

In the configuration of the second embodiment, too, substantially the same advantages as those of the first embodiment can be obtained. For example, an adequate voltage can be applied to the buried photodiode 13 from the reading gate electrode 21A. The signal charges can thus be read out of the buried photodiode 13 and supplied to the signal sensor 14 the most easily.

In the second embodiment, the reading gate electrode 21A is formed by the first and second electrode sections 21a and 21c. As in the first embodiment, the reading gate electrode 21A can be formed as a single component.

### Third Embodiment

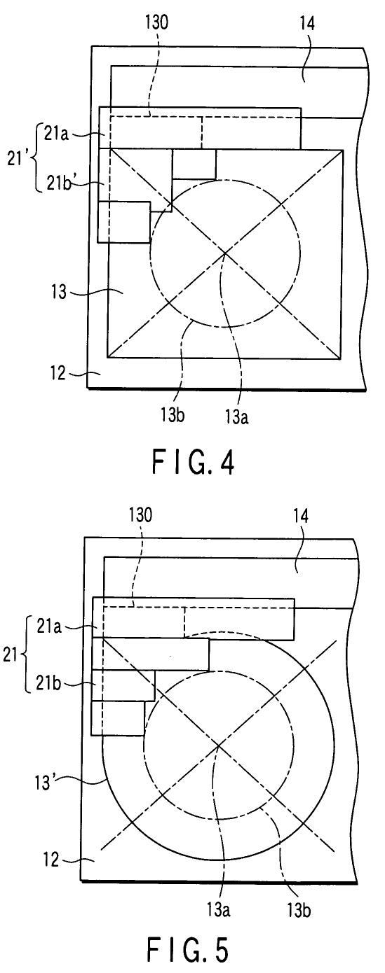

FIG. 4 shows a basic configuration of a CMOS sensor (solid-state imaging apparatus) according to a third embodiment of the present invention. Specifically, FIG. 4 shows one pixel (unit cell) of a pixel region of the CMOS sensor as an example of the configuration. The third embodiment is directed to another configuration (shape) of the second electrode section of the reading gate electrode according to the first embodiment. The same components as those of FIG. 1 are denoted by the same reference numerals and their detailed descriptions are omitted.

In the third embodiment, a first electrode section 21a and a second electrode section 21b′ compose a reading gate electrode (polysilicon) 21′ as shown in FIG. 4. More specifically, the first electrode section 21a is formed on an element isolation region 12 and between a signal sensor 14 and a buried photodiode 13, including part (leading region 130) of the buried photodiode 13. The first electrode section 21a is rectangular and extends along the signal sensor 14. On the other hand, the second electrode section 21b′ is formed by several electrode patterns. The distance between each of the electrode patterns and the center 13a of the buried photodiode 13 is almost fixed. In other words, the second electrode section 21b′ is provided on the buried photodiode 13 such that its electrode patterns are adjacent to the circumference of an image-forming region 13b with a fixed distance between the circumference and the center 13a of the buried photodiode 13. In the third embodiment, the second electrode section 21b′ is provided to correspond to almost one-fourth of the circumference of the image-forming region 13b. The electrode patterns of the second electrode section 21b′ are almost square and different in size, and they are arranged in a stepwise manner along the circumference of the image-forming region 13b.

In the configuration of the third embodiment, too, substantially the same advantages as those of the first embodiment can be obtained. For example, an adequate voltage can be applied to the buried photodiode 13 from the reading gate electrode 21′. The signal charges can thus be read out of the buried photodiode 13 and supplied to the signal sensor 14 the most easily.

In the third embodiment, the reading gate electrode 21′ is formed by the first and second electrode sections 21a and 21b′. As in the first embodiment, the reading gate electrode 21′ can be formed as a single component.

### Fourth Embodiment

FIG. 5 shows a basic configuration of a CMOS sensor (solid-state imaging apparatus) according to a fourth embodiment of the present invention. Specifically, FIG. 5 shows one pixel (unit cell) of a pixel region of the CMOS sensor as an example of the configuration. The fourth embodiment is directed to another configuration (shape) of the buried photodiode according to the first embodiment. The same components as those of FIG. 1 are denoted by the same reference numerals and their detailed descriptions are omitted.

In the fourth embodiment, a buried photodiode 13′ is almost circle as shown in FIG. 5. Except for this shape, the pixel has almost the same configuration as that of the pixel according to the first embodiment. More specifically, a first electrode section 21a and a second electrode section 21b compose a reading gate electrode (polysilicon) 21. The first electrode section 21a is formed on an element isolation region 12 and between a signal sensor 14 and a buried photodiode 13, including part (leading region 130) of the buried photodiode 13′. The first electrode section 21a is rectangular and extends along the signal sensor 14. On the other hand, the second electrode section 21b is formed by several electrode patterns. The distance between each of the electrode patterns and the center 13a of the buried photodiode 13′ is almost fixed. In other words, the second electrode section 21b is provided on the buried photodiode 13′ such that its electrode patterns are adjacent to the circumference of an image-forming region 13b with a fixed distance between the circumference and the center 13a of the buried photodiode 13′. In the fourth embodiment, the second electrode section 21b is provided to correspond to almost one-fourth of the circumference of the image-forming region 13b. The electrode patterns of the second electrode section 21b are almost square and different in size, and they are arranged in a stepwise manner along the circumference of the image-forming region 13b.

In the fourth embodiment in which the buried photodiode 13′ is circular, too, substantially the same advantages as those of the first embodiment can be obtained. For example, an adequate voltage can be applied to the buried photodiode 13′ from the reading gate electrode 21. The signal charges can thus be read out of the buried photodiode 13′ and supplied to the signal sensor 14 the most easily.

In the fourth embodiment, the reading gate electrode 21 is formed by the first and second electrode sections 21a and 21b. As in the first embodiment, the reading gate electrode 21 can be formed as a single component.

In the fourth embodiment, the reading gate electrode 21A shown in FIG. 3 or the reading gate electrode 21′ shown in FIG. 4 can be adopted.

### Fifth Embodiment

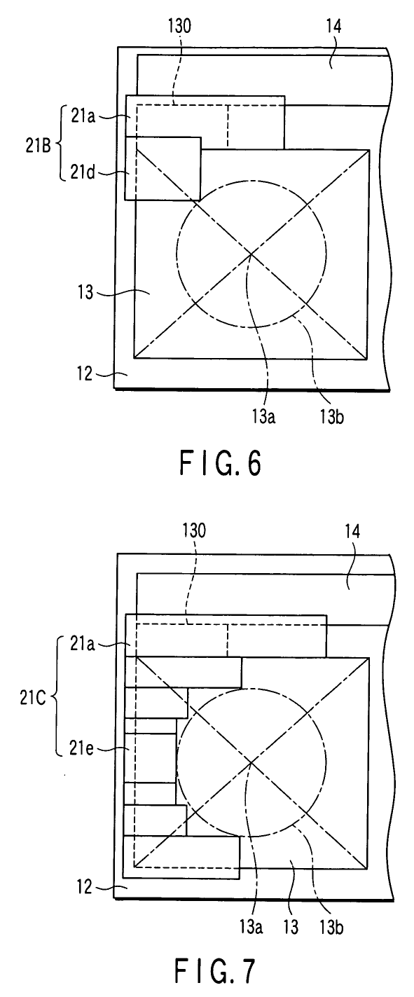

FIG. 6 shows a basic configuration of a CMOS sensor (solid-state imaging apparatus) according to a third embodiment of the present invention. Specifically, FIG. 6 shows one pixel (unit cell) of a pixel region of the CMOS sensor as an example of the configuration. The fifth embodiment is directed to another configuration (shape) of the second electrode section of the reading gate electrode according to the first embodiment. The same components as those of FIG. 1 are denoted by the same reference numerals and their detailed descriptions are omitted.

In the fifth embodiment, a first electrode section 21a and a second electrode section 21d compose a reading gate electrode (polysilicon) 21B as shown in FIG. 6. More specifically, the first electrode section 21a is formed on an element isolation region 12 and between a signal sensor 14 and a buried photodiode 13, including part (leading region 130) of the buried photodiode 13. The first electrode section 21a is rectangular and extends along the signal sensor 14. On the other hand, the second electrode section 21d is formed by at least one electrode pattern. The second electrode section 21d is provided on the buried photodiode 13 such that its electrode pattern is adjacent to the circumference of an image-forming region 13b with a fixed distance between the circumference and the center 13a of the buried photodiode 13. In the fifth embodiment, the second electrode section 21d is so provided that its portion is adjacent to one point of the circumference of the image-forming region 13b. The electrode pattern of the second electrode section 21d is almost square such that a portion of the pattern, which is adjacent to the circumference of the image-forming region 13b, becomes convex.

In the configuration of the fifth embodiment, too, substantially the same advantages as those of the first embodiment can be obtained. For example, an adequate voltage can be applied to the buried photodiode 13 from the reading gate electrode 21B. The signal charges can thus be read out of the buried photodiode 13 and supplied to the signal sensor 14 the most easily.

In the fifth embodiment, the reading gate electrode 21B is formed by the first and second electrode sections 21a and 21d. As in the first embodiment, the reading gate electrode 21B can be formed as a single component.

### Sixth Embodiment

FIG. 7 shows a basic configuration of a CMOS sensor (solid-state imaging apparatus) according to a sixth embodiment of the present invention. Specifically, FIG. 7 shows one pixel (unit cell) of a pixel region of the CMOS sensor as an example of the configuration. The sixth embodiment is directed to another configuration (shape) of the second electrode section of the reading gate electrode according to the first embodiment. The same components as those of FIG. 1 are denoted by the same reference numerals and their detailed descriptions are omitted.

In the sixth embodiment, a first electrode section 21a and a second electrode section 21e compose a reading gate electrode (polysilicon) 21C as shown in FIG. 7. More specifically, the first electrode section 21a is formed on an element isolation region 12 and between a signal sensor 14 and a buried photodiode 13, including part (leading region 130) of the buried photodiode 13. The first electrode section 21a is rectangular and extends along the signal sensor 14. On the other hand, the second electrode section 21e is formed by several electrode patterns. The distance between each of the electrode patterns and the center 13a of the buried photodiode 13 is almost fixed. The second electrode section 21e is provided on the buried photodiode 13 such that its electrode patterns are adjacent to the circumference of an image-forming region 13b with a fixed distance between the circumference and the center 13a of the buried photodiode 13. In the sixth embodiment, the second electrode section 21e is provided to correspond to almost one-half of the circumference of the image-forming region 13b. The electrode patterns of the second electrode section 21e are almost square and different in size, and they are arranged in a stepwise manner along the circumference of the image-forming region 13b.

In the configuration of the sixth embodiment, too, substantially the same advantages as those of the first embodiment can be obtained. For example, an adequate voltage can be applied to the buried photodiode 13 from the reading gate electrode 21C. The signal charges can thus be read out of the buried photodiode 13 and supplied to the signal sensor 14 the most easily.

In the sixth embodiment, the reading gate electrode 21C is formed by the first and second electrode sections 21a and 21e. As in the first embodiment, the reading gate electrode 21C can be formed as a single component.

### Seventh Embodiment

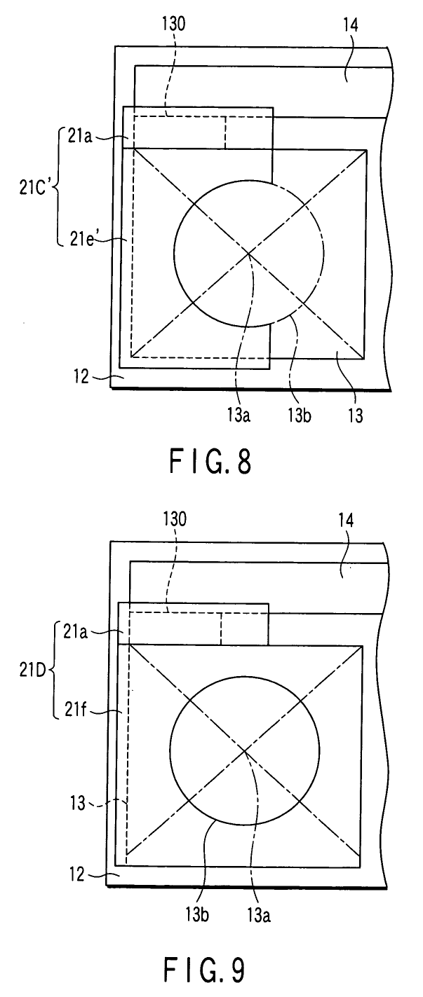

FIG. 8 shows a basic configuration of a CMOS sensor (solid-state imaging apparatus) according to a seventh embodiment of the present invention. Specifically, FIG. 8 shows one pixel (unit cell) of a pixel region of the CMOS sensor as an example of the configuration. The seventh embodiment is directed to another configuration (shape) of the second electrode section of the reading gate electrode according to the sixth embodiment. The same components as those of FIG. 7 are denoted by the same reference numerals and their detailed descriptions are omitted.

In the seventh embodiment, a first electrode section 21a and a second electrode section 21e′ compose a reading gate electrode (polysilicon) 21C′ as shown in FIG. 8. More specifically, the first electrode section 21a is formed on an element isolation region 12 and between a signal sensor 14 and a buried photodiode 13, including part (leading region 130) of the buried photodiode 13. The first electrode section 21a is rectangular and extends along the signal sensor 14. On the other hand, the second electrode section 21e′ is formed by at least one electrode pattern. The distance between the electrode pattern and the center 13a of the buried photodiode 13 is almost fixed. The second electrode section 21e′ is provided on the buried photodiode 13 such that its electrode pattern is adjacent to the circumference of an image-forming region 13b with a fixed distance between the circumference and the center 13a of the buried photodiode 13. In the seventh embodiment, the second electrode section 21e′ is provided to correspond to almost one-half of the circumference of the image-forming region 13b. The electrode pattern of the second electrode section 21e′ is curved such that a portion of the pattern which is adjacent to the circumference of the image-forming region 13b is curved.

In the configuration of the seventh embodiment, too, substantially the same advantages as those of the sixth embodiment can be obtained. For example, an adequate voltage can be applied to the buried photodiode 13 from the reading gate electrode 21C′. The signal charges can thus be read out of the buried photodiode 13 and supplied to the signal sensor 14 the most easily.

In the seventh embodiment, the reading gate electrode 21C′ is formed by the first and second electrode sections 21a and 21e′. As in the six embodiment, the reading gate electrode 21C′ can be formed as a single component.

### Eighth Embodiment

FIG. 9 shows a basic configuration of a CMOS sensor (solid-state imaging apparatus) according to an eighth embodiment of the present invention. Specifically, FIG. 9 shows one pixel (unit cell) of a pixel region of the CMOS sensor as an example of the configuration. The eighth embodiment is directed to another configuration (shape) of the second electrode section of the reading gate electrode according to the first embodiment. The same components as those of FIG. 1 are denoted by the same reference numerals and their detailed descriptions are omitted.

In the eighth embodiment, a first electrode section 21a and a second electrode section 21f compose a reading gate electrode (polysilicon) 21D as shown in FIG. 9. More specifically, the first electrode section 21a is formed on an element isolation region 12 and between a signal sensor 14 and a buried photodiode 13, including part (leading region 130) of the buried photodiode 13. The first electrode section 21a is rectangular and extends along the signal sensor 14. On the other hand, the second electrode section 21f is formed by at least one electrode pattern. The distance between the electrode pattern and the center 13a of the buried photodiode 13 is almost fixed. The second electrode section 21f is provided on the buried photodiode 13 such that its electrode pattern is adjacent to the circumference of an image-forming region 13b with a fixed distance between the circumference and the center 13a of the buried photodiode 13. In the eighth embodiment, the second electrode section 21f is provided to correspond to all the circumference of the image-forming region 13b. The electrode pattern of the second electrode section 21f is formed circularly (curved) such that a portion of the pattern which is adjacent to the circumference of the image-forming region 13b becomes circular.

In the configuration of the eighth embodiment, too, substantially the same advantages as those of the first embodiment can be obtained. For example, an adequate voltage can be applied to the buried photodiode 13 from the reading gate electrode 21D. The signal charges can thus be read out of the buried photodiode 13 and supplied to the signal sensor 14 the most easily.

In the eighth embodiment, the reading gate electrode 21D is formed by the first and second electrode sections 21a and 21f. As in the first embodiment, the reading gate electrode 21D can be formed as a single component.

### Ninth Embodiment

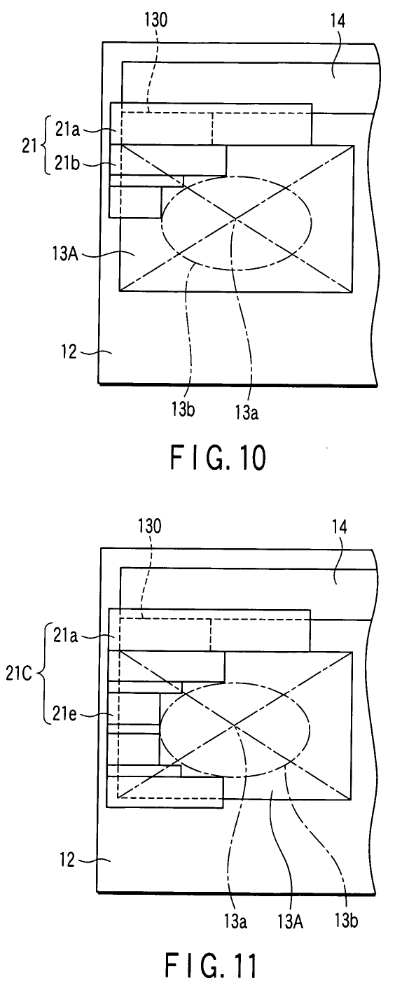

FIG. 10 shows a basic configuration of a CMOS sensor (solid-state imaging apparatus) according to a ninth embodiment of the present invention. Specifically, FIG. 10 shows one pixel (unit cell) of a pixel region of the CMOS sensor as an example of the configuration. The ninth embodiment is directed to another configuration (shape) of the buried photodiode according to the first embodiment. The same components as those of FIG. 1 are denoted by the same reference numerals and their detailed descriptions are omitted.

In the ninth embodiment, a buried photodiode 13A is almost horizontally elongated (rectangular) as shown in FIG. 10. Except for this shape, the pixel has almost the same configuration as that of the pixel according to the first embodiment. More specifically, a first electrode section 21a and a second electrode section 21b compose a reading gate electrode (polysilicon) 21. The first electrode section 21a is formed on an element isolation region 12 and between a signal sensor 14 and a buried photodiode 13, including part (leading region 130) of the buried photodiode 13′. The first electrode section 21a is rectangular and extends along the signal sensor 14. On the other hand, the second electrode section 21b is formed by several electrode patterns. The distance between each of the electrode patterns and the center 13a of the buried photodiode 13A is almost fixed. The second electrode section 21b is provided on the buried photodiode 13A such that its electrode patterns are adjacent to the circumference of an image-forming region 13b with a fixed distance between the circumference and the center 13a of the buried photodiode 13A. In the ninth embodiment, the second electrode section 21b is provided to correspond to almost one-fourth of the circumference of the image-forming region 13b. The electrode patterns of the second electrode section 21b are rectangular and different in size, and they are arranged in a stepwise manner along the circumference of the image-forming region 13b.

In the ninth embodiment in which the buried photodiode 13A is horizontally elongated, too, substantially the same advantages as those of the first embodiment can be obtained. For example, an adequate voltage can be applied to the buried photodiode 13A from the reading gate electrode 21. The signal charges can thus be read out of the buried photodiode 13A and supplied to the signal sensor 14 the most easily.

In the ninth embodiment, the reading gate electrode 21 is formed by the first and second electrode sections 21a and 21b. As in the first embodiment, the reading gate electrode 21 can be formed as a single component.

In the ninth embodiment, the reading gate electrode 21A shown in FIG. 3, the reading gate electrode 21′ shown in FIG. 4, the reading gate electrode 21B shown in FIG. 6, the reading gate electrode 21C′ shown in FIG. 8, or the reading gate electrode 21D shown in FIG. 9 can be adopted. As shown in FIG. 11, the reading gate electrode 21C shown in FIG. 7 can also be adopted.

In the pixel having the horizontally-elongated buried photodiode 13A, the reading gate electrode (polysilicon) 21C including the first and second electrode sections 21a and 21e can be provided as shown in FIG. 11. In this configuration, too, substantially the same advantages as those of the ninth embodiment can be obtained. For example, an adequate voltage can be applied to the buried photodiode 13A from the reading gate electrode 21C. The signal charges can thus be read out of the buried photodiode 13A and supplied to the signal sensor 14 the most easily.

In the ninth embodiment, the reading gate electrode 21C is formed by the first and second electrode sections 21a and 21e. However, the reading gate electrode 21C can be formed as a single component.

### Tenth Embodiment

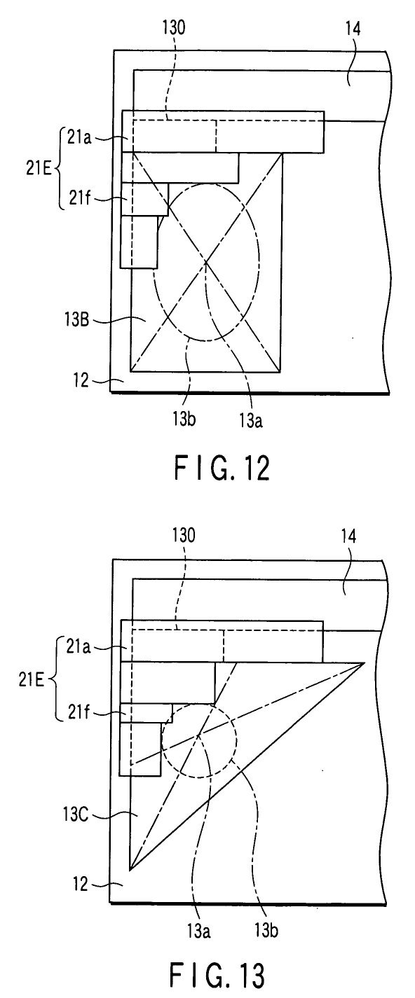

FIG. 12 shows a basic configuration of a CMOS sensor (solid-state imaging apparatus) according to a tenth embodiment of the present invention. Specifically, FIG. 12 shows one pixel (unit cell) of a pixel region of the CMOS sensor as an example of the configuration. The tenth embodiment is directed to another configuration (shape) of the buried photodiode according to the first embodiment. The same components as those of FIG. 1 are denoted by the same reference numerals and their detailed descriptions are omitted.

In the tenth embodiment, a buried photodiode 13B is almost vertically elongated (rectangular) as shown in FIG. 12. Except for this shape, the pixel has almost the same configuration as that of the pixel according to the first embodiment. More specifically, a first electrode section 21a and a second electrode section 21f compose a reading gate electrode (polysilicon) 21E. The first electrode section 21a is formed on an element isolation region 12 and between a signal sensor 14 and a buried photodiode 13B, including part (leading region 130) of the buried photodiode 13B. The first electrode section 21a is rectangular and extends along the signal sensor 14. On the other hand, the second electrode section 21f is formed by several electrode patterns. The distance between each of the electrode patterns and the center 13a of the buried photodiode 13B is almost fixed. The second electrode section 21f is provided on the buried photodiode 13B such that its electrode patterns are adjacent to the circumference of an image-forming region 13b with a fixed distance between the circumference and the center 13a of the buried photodiode 13B. In the tenth embodiment, the second electrode section 21f is provided to correspond to almost one-fourth of the circumference of the image-forming region 13b. The electrode patterns of the second electrode section 21f are rectangular and different in size, and they are arranged in a stepwise manner along the circumference of the image-forming region 13b.

In the tenth embodiment in which the buried photodiode 13B is vertically elongated, too, substantially the same advantages as those of the first embodiment can be obtained. For example, an adequate voltage can be applied to the buried photodiode 13B from the reading gate electrode 21E. The signal charges can thus be read out of the buried photodiode 13B and supplied to the signal sensor 14 the most easily.

In the tenth embodiment, the reading gate electrode 21E is formed by the first and second electrode sections 21a and 21f. As in the first embodiment, the reading gate electrode 21E can be formed as a single component.

In the tenth embodiment, the reading gate electrode 21 shown in FIGS. 1, 5 and 10, the reading gate electrode 21A shown in FIG. 3, the reading gate electrode 21′ shown in FIG. 4, the reading gate electrode 21B shown in FIG. 6, the reading gate electrode 21C shown in FIGS. 7 and 11, the reading gate electrode 21C′ shown in FIG. 8, or the reading gate electrode 21D shown in FIG. 9 can be adopted.

### Eleventh Embodiment

FIG. 13 shows a basic configuration of a CMOS sensor (solid-state imaging apparatus) according to an eleventh embodiment of the present invention. Specifically, FIG. 13 shows one pixel (unit cell) of a pixel region of the CMOS sensor as an example of the configuration. The eleventh embodiment is directed to another configuration (shape) of the buried photodiode according to the tenth embodiment. The same components as those of FIG. 12 are denoted by the same reference numerals and their detailed descriptions are omitted.

In the eleventh embodiment, a buried photodiode 13C is almost triangular as shown in FIG. 13. Except for this shape, the pixel has almost the same configuration as that of the pixel according to the tenth embodiment. More specifically, a first electrode section 21a and a second electrode section 21f compose a reading gate electrode (polysilicon) 21E. The first electrode section 21a is formed on an element isolation region 12 and between a signal sensor 14 and a buried photodiode 13C, including part (leading region 130) of the buried photodiode 13C. The first electrode section 21a is rectangular and extends along the signal sensor 14. On the other hand, the second electrode section 21f is formed by several electrode patterns. The distance between each of the electrode patterns and the center 13a of the buried photodiode 13C is almost fixed. The second electrode section 21f is provided on the buried photodiode 13C such that its electrode patterns are adjacent to the circumference of an image-forming region 13b with a fixed distance between the circumference and the center 13a of the buried photodiode 13C. In the eleventh embodiment, the second electrode section 21f is provided to correspond to almost one-third of the circumference of the image-forming region 13b. The electrode patterns of the second electrode section 21f are rectangular and different in size, and they are arranged in a stepwise manner along the circumference of the image-forming region 13b.

In the eleventh embodiment in which the buried photodiode 13C is rectangular, too, substantially the same advantages as those of the first embodiment can be obtained. For example, an adequate voltage can be applied to the buried photodiode 13C from the reading gate electrode 21E. The signal charges can thus be read out of the buried photodiode 13C and supplied to the signal sensor 14 the most easily.

In the eleventh embodiment, the reading gate electrode 21E is formed by the first and second electrode sections 21a and 21f. As in the tenth embodiment, the reading gate electrode 21E can be formed as a single component.

In the eleventh embodiment, the reading gate electrode 21 shown in FIGS. 1, 5 and 10, the reading gate electrode 21A shown in FIG. 3, the reading gate electrode 21′ shown in FIG. 4, the reading gate electrode 21B shown in FIG. 6, the reading gate electrode 21C shown in FIGS. 7 and 11, the reading gate electrode 21C′ shown in FIG. 8, or the reading gate electrode 21D shown in FIG. 9 can be adopted.

In each of the above embodiments, the semiconductor substrate is not limited to a P-type substrate. Even though an N-type substrate is used, the same advantages can be obtained.

FIG. 1 shows a CMOS sensor using a selecting transistor (address transistor). However, the present invention can be applied to a CMOS sensor without the selecting transistor.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A solid-state imaging apparatus comprising:
a semiconductor substrate;
a photoelectric converter which is formed in a surface region of the semiconductor substrate and converts light into signal charges; and
reading electrodes which read out the signal charges and supply the signal charges to a signal sensor, at least some of the reading electrodes being arranged adjacent to a circumference of an image-forming region with a fixed distance between the circumference and a center of the photoelectric converter.

2. The solid-state imaging apparatus according to claim 1, wherein the photoelectric converter has a lowest portion of a single potential corresponding to each of the signal charges under the reading electrodes.

3. The solid-state imaging apparatus according to claim 1, wherein the reading electrodes include a first electrode section provided between the signal sensor and the photoelectric converter, and a second electrode section connected to the first electrode section and provided adjacent to the circumference of the image-forming region.

4. The solid-state imaging apparatus according to claim 3, wherein the second electrode section has one of a curved portion and a convex portion, which is adjacent to the circumference of the image-forming region.

5. The solid-state imaging apparatus according to claim 3, wherein the second electrode section has at least one electrode pattern.

6. The solid-state imaging apparatus according to claim 5, wherein the one electrode pattern is formed along the circumference of the image-forming region.

7. The solid-state imaging apparatus according to claim 3, wherein the second electrode section has a plurality of electrode patterns.

8. The solid-state imaging apparatus according to claim 7, wherein the electrode patterns are arranged along the circumference of the image-forming region.

9. The solid-state imaging apparatus according to claim 1, wherein the photoelectric converter is square.

10. The solid-state imaging apparatus according to claim 1, wherein the photoelectric converter is rectangular.

11. The solid-state imaging apparatus according to claim 1, wherein the photoelectric converter is horizontally elongated.

12. The solid-state imaging apparatus according to claim 1, wherein the photoelectric converter is vertically elongated.

13. The solid-state imaging apparatus according to claim 1, wherein the photoelectric converter is circular.

14. The solid-state imaging apparatus according to claim 1, wherein the photoelectric converter is triangular.

15. The solid-state imaging apparatus according to claim 3, wherein the second electrode section is provided to correspond to one-fourth of the circumference of the image-forming region.

16. The solid-state imaging apparatus according to claim 3, wherein the second electrode section is provided to correspond to one-third of the circumference of the image-forming region.

17. The solid-state imaging apparatus according to claim 3, wherein the second electrode section is provided to correspond to one-half of the circumference of the image-forming region.

18. The solid-state imaging apparatus according to claim 3, wherein the second electrode section is provided to correspond to all the circumference of the image-forming region.
